(19) United States
(12) Patent Application Publication
(10) Pub. No.: US 2025/0014989 A1
(43) Pub. Date: Jan. 9, 2025

(54) PACKAGE SUBSTRATE AND FABRICATING METHOD THEREOF

(71) Applicant: AaltoSemi Inc., Nanjing City (CN)

(72) Inventors: Jiun-Hua CHIUE, Nanjing City (CN); Yin-Ju CHEN, Nanjing City (CN); Min-Yao CHEN, Nanjing City (CN); Andrew C. CHANG, Nanjing City (CN)

(73) Assignee: AaltoSemi Inc., Nanjing City (CN)

(21) Appl. No.: 18/763,608

(22) Filed: Jul. 3, 2024

(30) Foreign Application Priority Data
Jul. 5, 2023 (CN) 202310820824.2

(51) Int. Cl. H01L 23/522; H01L 23/528; H01L 23/532

(52) U.S. Cl. CPC H01L 23/5226; H01L 23/5283; H01L 23/53295

(57) ABSTRACT

A package substrate is provided, in which the package substrate is fabricated by using a thin core board body with a thickness of at most 20 micrometers, such that the package substrate can meet the requirement of thinning and avoid reliability problems. A method of fabricating the package substrate is also provided.

### CROSS-REFERENCE TO RELATED APPLICATION

This application claims the benefit of priority to Chinese Patent Application No. 202310820824.2, filed Jul. 5, 2023, the entire contents of which are hereby incorporated by reference.

### BACKGROUND

### Technical Field

The present disclosure relates to a semiconductor package fabricating process, and more particularly, to a package substrate and a fabricating method thereof for improving reliability.

### Description of Related Art

Currently, the technologies applied in the field of chip packaging include package modules such as Chip Scale Package (CSP), Direct Chip Attach (DCA), or Multi-Chip Module (MCM) Package. As the functionality of end-products increases, semiconductor chips need to have more input/output (I/O) connections, and the number of external pads on the package substrate used to carry semiconductor chips increases accordingly.

FIG. 1 is a schematic cross-sectional view showing a conventional package substrate 1 of the prior art. As shown in FIG. 1, the package substrate 1 includes a core board body 10. The core board body 10 has a first side 10a and a second side 10b opposing the first side 10a, and the first side 10a and the second side 10b of the core board body 10 are each provided with a circuit structure 11, wherein the circuit structure 11 includes a plurality of insulating layers 111 and a plurality of circuit layers 110 formed on each of the insulating layers 111, and the core board body 10 has a plurality of conductive vias 100 connecting the first side 10a and the second side 10b to electrically connect the circuit layers 110.

Currently, the circuit structure 11 is made by conventional build-up process to lay out the wires on the prepreg (PP) with glass fibers, thereby forming the symmetric package substrate 1.

However, the method of fabricating the conventional package substrate 1 uses the core board body 10 with an extremely thick thickness d0 (at least 40 micrometers) for the fabrication of the circuit structure 11. As such, it is difficult for the package substrate 1 to meet the requirement of thinning.

In addition, if the thinner core board body 10 is used to fabricate the circuit structure 11, the core board body 10 is susceptible to wrinkles or bends during the fabrication of the circuit structure 11, resulting in the circuit layers 110 being misaligned, uneven, or having other reliability problems.

Therefore, how to overcome the various problems of the above-mentioned prior art has become an urgent issue to be solved.

### SUMMARY

In view of the various shortcomings of the prior art, the present disclosure provides a package substrate, which comprises: a core board body having a first side, a second side opposing the first side, and at least one conductive via connecting the first side and the second side, wherein a thickness of the core board body is less than or equal to 20 micrometers; a first circuit layer formed on the first side of the core board body and electrically connected to the conductive via; and a second circuit layer formed on the second side of the core board body and electrically connected to the conductive via.

The present disclosure further provides a method of fabricating a package substrate, and the method comprises: providing a carrier, wherein the carrier comprises a support board body having a metal layer, and a substrate is formed on two opposite sides of the support board body, and a total thickness of the carrier and the substrate is at least 60 micrometers, wherein the substrate has a core board body, the core board body has a first side and a second side opposing the first side, and the core board body is bonded to the metal layer of the carrier via the second side thereof; forming a first circuit layer on the first side of the core board body, and forming at least one conductive via connecting the first side and the second side to electrically connect the first circuit layer to the conductive via, wherein a thickness of the core board body is less than or equal to 20 micrometers; removing the carrier; bonding the first side of the core board body to two opposite sides of a support member, respectively; forming a second circuit layer on the second side of the core board body to electrically connect the second circuit layer to the conductive via; and removing the support member.

In the aforementioned package substrate and method, the present disclosure further comprises forming a first build-up structure on the first side of the core board body and on the first circuit layer, wherein the first build-up structure comprises at least one first insulating layer formed on the core board body and a first wiring layer formed on the first insulating layer and electrically connected to the first circuit layer. For example, a thickness of the first insulating layer is less than or equal to 10 micrometers.

In the aforementioned package substrate and method, the present disclosure further comprises forming a second build-up structure on the second side of the core board body and on the second circuit layer, wherein the second build-up structure comprises at least one second insulating layer formed on the core board body and a second wiring layer formed on the second insulating layer and electrically connected to the second circuit layer. For example, a thickness of the second insulating layer is less than or equal to 10 micrometers.

In view of the above, in the package substrate and fabricating method thereof of the present disclosure, the package substrate is made by using the core board body with a thickness thinner than that of the conventional core board body, such that the package substrate can meet the requirement of thinning.

Furthermore, when the core board body with a thin thickness is used to fabricate the package substrate, the total thickness of the substrate on both sides of the carrier is at least 60 micrometers to avoid problems such as wrinkles or bends in the core board body during the fabrication of the first circuit layer (and the first build-up structure). Therefore, compared to the prior art, the package substrate of the present disclosure can avoid the reliability problems such as misalignment or unevenness of the first circuit layer and the second circuit layer (and the first wiring layer and the second wiring layer).

### BRIEF DESCRIPTION OF THE DRAWINGS

FIG. 1 is a schematic cross-sectional view showing a conventional semiconductor package.

FIG. 2A to FIG. 2H are schematic cross-sectional views showing a method of fabricating a package substrate according to a first embodiment of the present disclosure.

FIG. 3A to FIG. 3G are schematic cross-sectional views showing a method of fabricating a package substrate according to a second embodiment of the present disclosure.

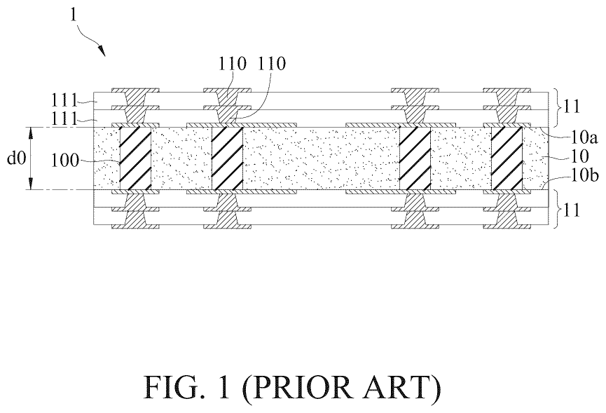

### DETAILED DESCRIPTION

The following describes the implementation of the present disclosure with examples. Those skilled in the art can easily understand other advantages and effects of the present disclosure from the content disclosed in this specification.

It should be understood that the structures, ratios, sizes, and the like shown in the drawings attached to this specification are only used to exemplify the content disclosed in the specification for the understanding and reading of people skilled in this art, and are not intended to limit the scope of the present disclosure. The present disclosure may also be implemented or applied as described in the various examples. It is also possible to modify or alter the following examples for carrying out the present disclosure without violating its spirit and scope, for different aspects and applications. One of skill in the art will appreciate that structural modifications, changes in proportions, or adjustments in size of the disclosed embodiments will fall within the scope of the technical content disclosed in the present disclosure without affecting the effects that can be produced and the purposes that can be achieved by the present disclosure. Meanwhile, terms such as “on,” “first,” “second,” “a,” “one” and the like are merely used for clear explanation rather than limiting the practicable scope of the present disclosure, and thus, alterations or adjustments of the relative relationships thereof without essentially altering the technical content should still be considered in the practicable scope of the present disclosure. Meanwhile, terms such as “upper”, “first” and “second” recited in the specification are also used for clear description but not for defining the scope capable of being implemented by the present disclosure, the change or adjustment of their relative relationship without substantial alteration of the technical contents are also considered within the implementation scope of the present disclosure. Unless stated otherwise, “comprising”, “containing” or “having” particular elements used herein means that other elements such as units, components, structures, regions, parts, devices, systems, steps and connection relationships can be also included rather than excluded. Unless expressly stated otherwise, the singular forms “a”, “an” and “the” also include the plural forms, and the “or” and “and/or” can be used interchangeably herein. The numeric ranges described herein are inclusive and combinable, and any value falling into the numeric ranges described herein can be used as the upper or lower limit to derive a subrange. For example, a numeric range of “25-200” should be understood to include any subranges between the endpoints 25 and 200, e.g., subranges of 25-150, 30-200, 30-150, etc. In addition, a value falling into each range described herein (e.g., between the upper and lower limits) should be considered to be included in the range described herein.

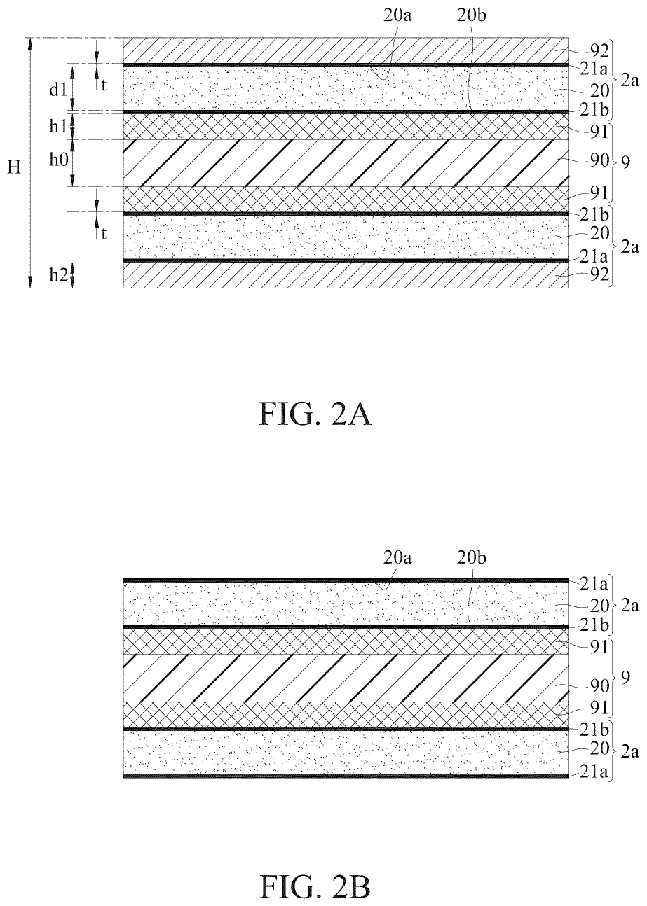

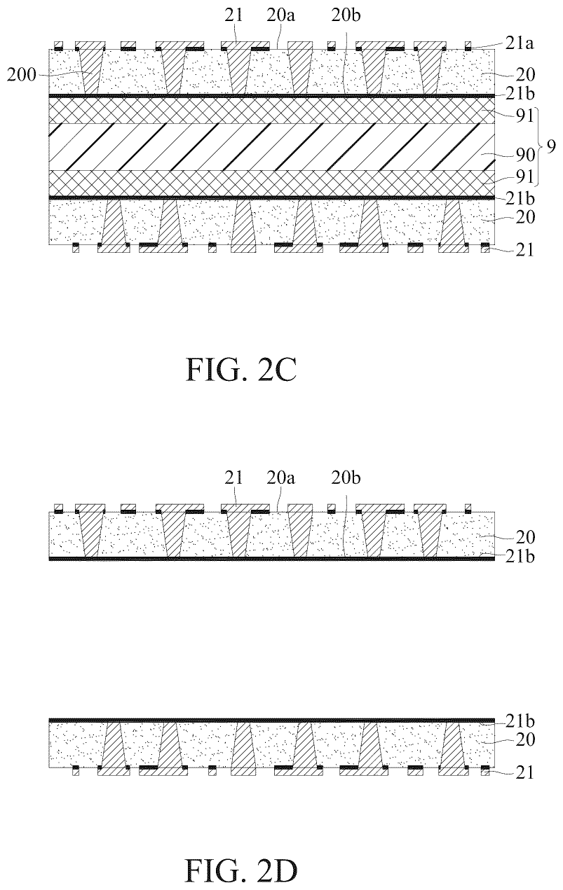

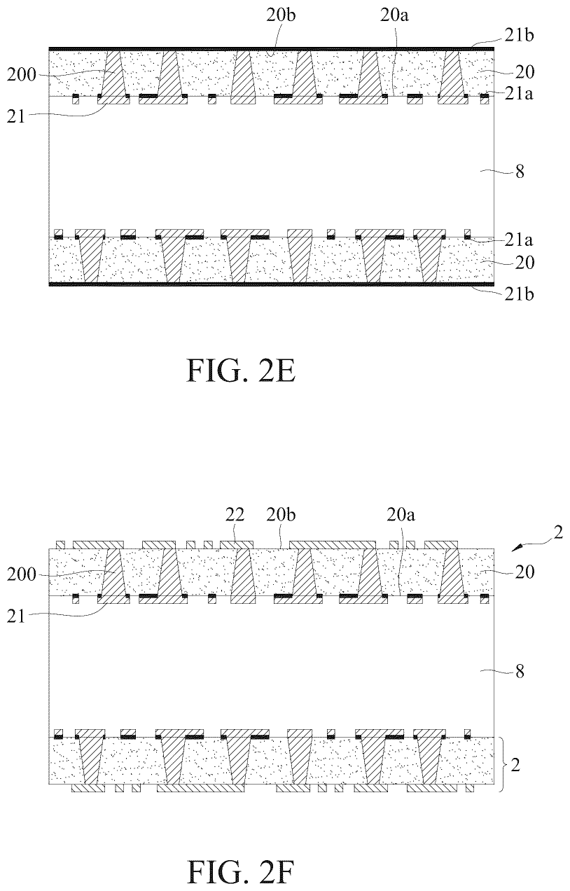

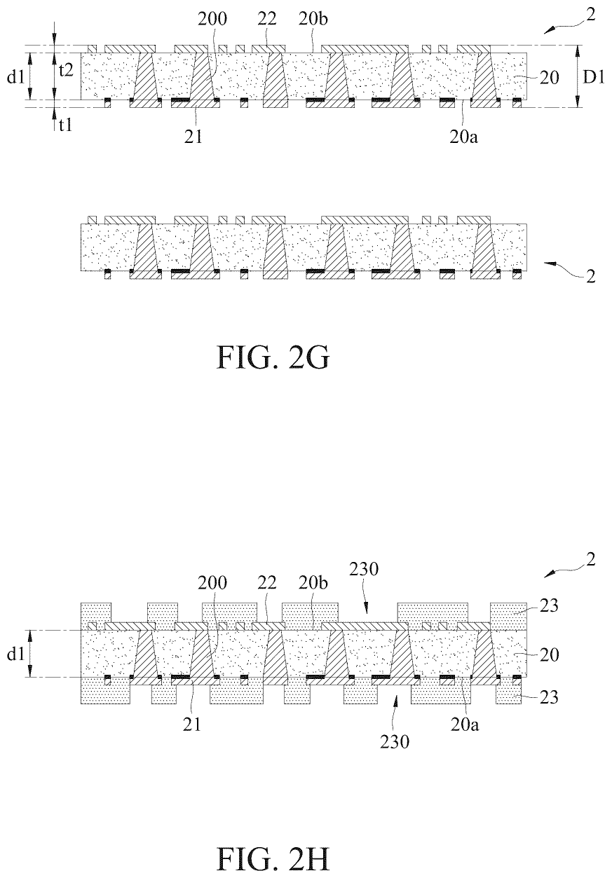

FIG. 2A to FIG. 2H are schematic cross-sectional views showing a method of fabricating a package substrate 2 according to a first embodiment of the present disclosure.

As shown in FIG. 2A, a carrier 9 is provided. The carrier 9 includes a support board body 90 having metal layers 91, such as a copper foil substrate, and a substrate 2a is formed on each of the opposite sides of the support board body 90.

In an embodiment, the copper foil substrate is a temporary carrier. The material of the support board body 90 thereof is a dielectric material such as prepreg (PP) in flame resistant/retardant 4 (FR-4) specification, and the substrate 2a has a core board body 20 having a first side 20a and a second side 20b opposing the first side 20a. For example, the core board body 20 may be an organic polymer board containing bismaleimide triazine (BT), prepreg (PP) with glass fibers, or other boards.

Moreover, a seeding layer 21a and a seeding layer 21b may be formed on the first side 20a and the second side 20b of the core board body 20 respectively, and a hardened layer 92 may be formed on the seeding layer 21a of the first side 20a of the core board body 20. For example, the hardened layer 92 is a copper foil, and the substrate 2a is pressed onto the metal layer 91 on opposite sides of the support board body 90 by the hardened layer 92.

Furthermore, the thickness t of each of the seeding layers 21a, 21b is extremely thin (e.g., 3 micrometers), and the thickness h1 of the metal layer 91 and the thickness h2 of the hardened layer 92 may be the same. For example, the thickness h1 of the metal layer 91 and the thickness h2 of the hardened layer 92 are 18 micrometers (μm).

In addition, the thickness h0 of the support board body 90 and the thickness d1 of the core board body 20 may be the same. For example, the thickness h0 of the support board body 90 and the thickness dl of the core board body 20 are less than or equal to 20 micrometers (μm).

As shown in FIG. 2B, the hardened layer 92 is removed to expose the seeding layer 21a on the first side 20a of the core board body 20.

As shown in FIG. 2C, a first circuit layer 21 is formed on the core board body 20 by the seeding layer 21a on the first side 20a of the core board body 20, and at least one conductive via 200 electrically connected to the first circuit layer 21 is formed in the core board body 20. In an embodiment, the process of forming the conductive via 200 may start with laser

cauterizing at least one via in the core board body 20, and then forming a metal material in the via to act as a cylindrical conductor. For example, the conductive via 200 may be formed at the same time as the first circuit layer 21 is formed.

In addition, the first circuit layer 21 is made by electroplating metal (e.g., copper) or other means using a redistribution layer (RDL) specification, and then the excess seeding layer 21a is removed by etching.

As shown in FIG. 2D, the support board body 90 and the metal layer 91 thereon are removed to expose the seeding layer 21b on the second side 20b of the core board body 20.

As shown in FIG. 2E, a support member 8 is provided to symmetrically bond the core board body 20 on each of the opposite sides of the support member 8.

In an embodiment, the support member 8 is a thermal release film, and the core board body 20 is pressed onto the support member 8 via the first circuit layer 21 of the first side 20a thereof, such that the seeding layer 21b on the second side 20b of the core board body 20 is facing outward. For example, the first circuit layer 21 is embedded in the thermal release film.

As shown in FIG. 2F, a second circuit layer 22 is formed on the core board body 20 by the seeding layer 21b of the second side 20b of the core board body 20 to obtain the package substrate 2, and the second circuit layer 22 is electrically connected to the conductive via 200.

In an embodiment, the second circuit layer 22 is fabricated by a patterning process. For example, the seeding layer 21b may be removed first, and then multiple patterned resist layers may be formed on the core board body 20 by means of exposure development. Subsequently, metal plating may be applied to the openings of the patterned resist layers, and then the patterned resist layers may be removed. It should be understood that the fabrication method of the first circuit layer 21 may also be adopted, such that part of the seeding layer 21b is retained below the second circuit layer 22.

As shown in FIG. 2G, the support member 8 is heated to separate the support member 8 from the package substrate 2 so as to obtain the package substrate 2 having specifications of multiple circuit layers (the first circuit layer 21 and the second circuit layer 22).

In an embodiment, the thickness D1 of the package substrate 2 is greater than or equal to about 50 micrometers, and the thickness t1 of the first circuit layer 21 and the thickness t2 of the second circuit layer 22 are greater than or equal to 15 micrometers.

In addition, as shown in FIG. 2H, an insulating protective layer 23, made of such as solder-resist material, may be formed on the first side 20a and the second side 20b of the core board body 20. For example, the insulating protective layer 23 has a plurality of openings 230 that expose the first circuit layer 21 and the second circuit layer 22, such that the exposed portions of the first circuit layer 21 and the second circuit layer 22 serve as electrical contact pads for bonding the solder material. Further, in a subsequent process, the package substrate 2 may be used to connect at least one electronic component or circuit board via the solder material.

The electronic component is an active component, a passive component, or a combination of the active component and the passive element, wherein the active component is, for example, a semiconductor chip, and the passive component is, for example, a resistor, a capacitor, or an inductor.

Also, the removal of the support member 8 (thermal release film) requires a decomposition temperature of about 180° C. to 220° C. (e.g., 200° C.), which is higher than the glass transition temperature (Tg) of the PP material (or the core board body 20).

Therefore, compared to the conventional thicker core board body 10 with the thickness d0 of at least 40 μm, the method of the present disclosure mainly conforms to the need for thinning of the package substrate 2 by means of using the thinner core board body 20 with the thickness d1 of at most 20 μm to fabricate the package substrate 2.

Furthermore, when using the thinner core board body 20 with the thickness dl of at most 20 μm to fabricate the package substrate 2 (compared to the conventional thicker core board body 10 with the thickness d0 of at least 40 μm), the total thickness H of the substrate 2a on both sides of the carrier 9 is set to be at least 60 μm to avoid problems such as wrinkles or bends of the core board body 20 during the fabrication of the first circuit layer 21. Hence, compared to the prior art, the package substrate 2 of the present disclosure can avoid problems of reliability such as misalignment or unevenness of the first circuit layer 21 and the second circuit layer 22.

Also, by using the thermal release film as the support member 8, the core board body 20 can be bonded onto the opposite sides of the support member 8 to facilitate mass production.

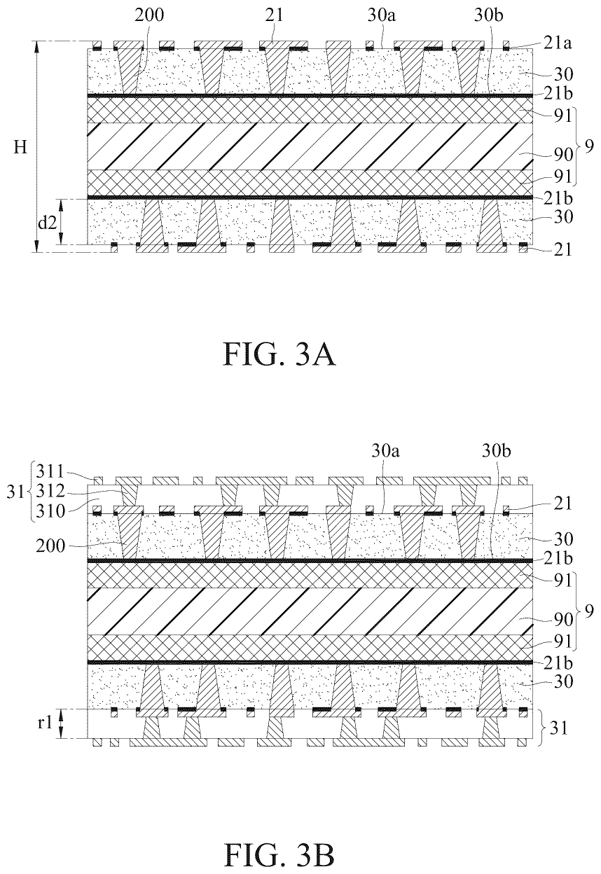

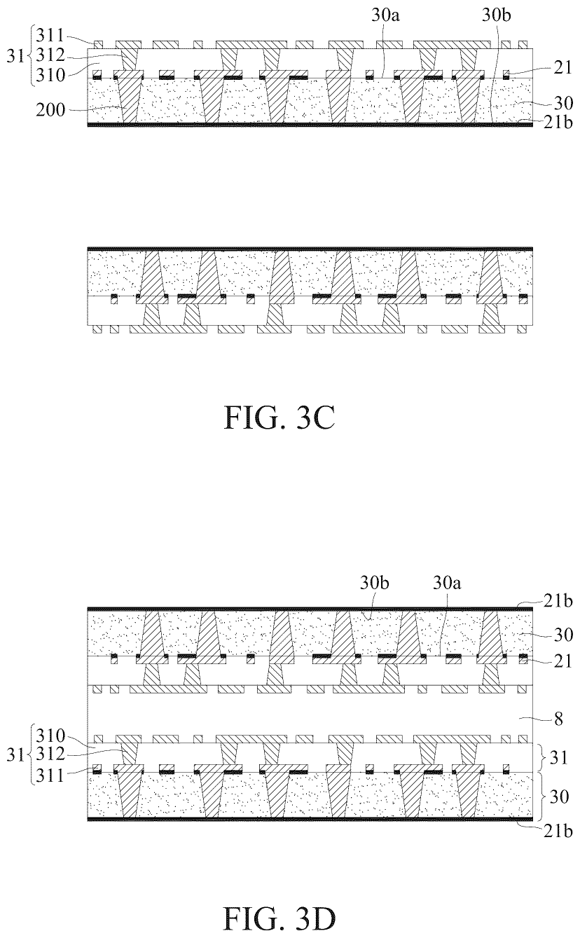

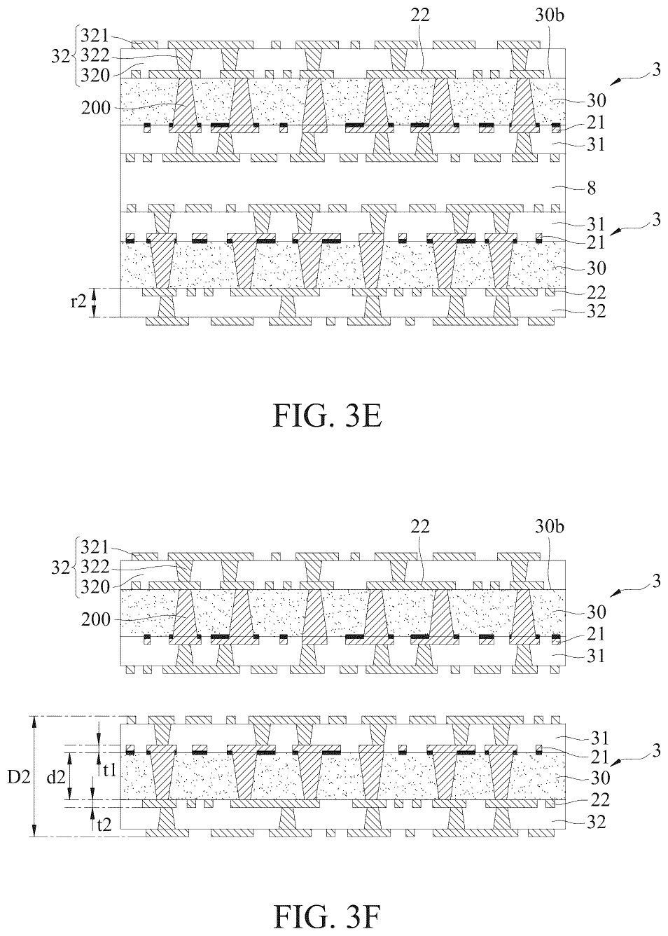

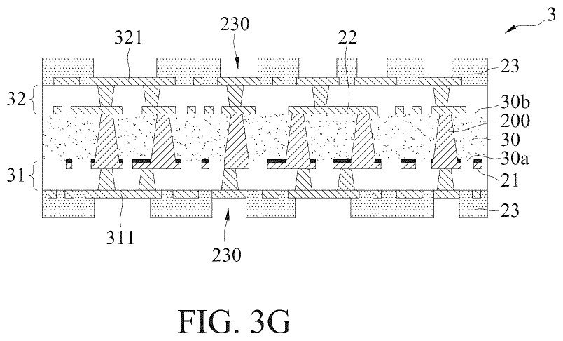

FIG. 3A to FIG. 3G are schematic cross-sectional views showing a method of fabricating a package substrate 3 according to a second embodiment of the present disclosure. The difference between the second embodiment and the first embodiment lies in the process of forming the build-up structure, and the other processes are generally the same. Accordingly, the following is not going to repeat the similarities.

As shown in FIG. 3A to FIG. 3B, following the process shown in FIG. 2C, a first build-up structure 31 is formed on a first side 30a of a core board body 30 and on the first circuit layer 21.

In an embodiment, the first build-up structure 31 includes at least one first insulating layer 310, a first wiring layer 311 formed on the first insulating layer 310 and a plurality of first conductive blind vias 312 formed in the first insulating layer 310 for electrically connecting the first circuit layer 21 to the first wiring layer 311. For example, the first wiring layer 311 and the first conductive blind vias 312 are integrally formed by a patterning process using electroplated metal (e.g., copper) or other means, and the first insulating layer 310 is a dielectric layer made of such as polybenzoxazole (PBO), polyimide (PI), prepreg (PP) with glass fibers, or other dielectric materials.

Moreover, the thickness r1 of the first insulating layer 310 is less than or equal to 10 um to facilitate the fabrication of more layers of the first wiring layer 311, such as 6 layers or 8 layers. Therefore, by utilizing the build-up method, the first build-up structure 31 may add multiple layers of the first insulating layer 310 as required so as to form multiple layers of the first wiring layer 311.

In addition, the thickness d2 of the core board body 30 is less than the thickness d1 (20 μm) of the core board body 20 of the first embodiment. For example, the thickness d2 of the core board body 30 is 10 micrometers (μm).

As shown in FIG. 3C, the support board body 90 and the metal layer 91 thereon are removed to expose the seeding layer 21b on a second side 30b of the core board body 30.

As shown in FIG. 3D, the support member 8 is provided to symmetrically bond the core board body 30 on each of the opposite sides of the support member 8.

In an embodiment, the support member 8 is a thermal release film, and the core board body 30 is pressed onto the support member 8 via the first build-up structure 31 of the first side 30a thereof, such that the seeding layer 21b on the second side 30b of the core board body 30 faces outward. For example, the first wiring layer 311 is embedded in the thermal release film.

As shown in FIG. 3E, the second circuit layer 22 is formed on the core board body 30 by the seeding layer 21b on the second side 30b of the core board body 30 to electrically connect the second circuit layer 22 to the conductive via 200. Subsequently, a second build-up structure 32 is formed on the second side 30b of the core board body 30 and on the second circuit layer 22 to obtain the package substrate 3.

In an embodiment, the second build-up structure 32 includes at least one second insulating layer 320, a second wiring layer 321 formed on the second insulating layer 320 and a plurality of second conductive blind vias 322 formed in the second insulating layer 320 for electrically connecting the second circuit layer 22 to the second wiring layer 321. For example, the second wiring layer 321 and the second conductive blind vias 322 are integrally formed by a patterning process using electroplated metal (e.g., copper) or other means, and the second insulating layer 320 is a dielectric layer made of such as polybenzoxazole (PBO), polyimide (PI), prepreg (PP) with glass fibers, or other dielectric materials.

Furthermore, the thickness r2 of the second insulating layer 320 is less than or equal to 10 μm to facilitate the fabrication of more layers of the second wiring layer 321, such as 6 layers or 8 layers. Therefore, by utilizing the build-up method, the second build-up structure 32 may add multiple layers of the second insulating layer 320 as required to form multiple layers of the second wiring layer 321.

In addition, the process of the second circuit layer 22 may refer to the patterning process described in the first embodiment.

As shown in FIG. 3F, the support member 8 is heated to separate the support member 8 from the package substrate 3 to obtain multiple package substrates 3 with build-up structures.

In an embodiment, the thickness D2 of the package substrate 3 is greater than or equal to 60 μm, and the thickness t1 of the first circuit layer 21 and the thickness t2 of the second circuit layer 22 are greater than or equal to 15 μm.

Moreover, as shown in FIG. 3G, the insulating protective layer 23, made of such as solder-resist material, may be formed on the first build-up structure 31 and the second build-up structure 32, respectively. For example, the insulating protective layer 23 has the plurality of openings 230 exposing the first wiring layer 311 and the second wiring layer 321, such that the exposed portions of the first wiring layer 311 and the second wiring layer 321 serve as electrical contact pads for bonding the solder material.

Further, based on the configuration of the multiple insulating layers (the core board body 30, the first insulating layer 310 and the second insulating layer 320) of the package substrate 3, the removal of the thermal release film requires a higher decomposition temperature of about 300° C.

Therefore, by using the thinner core board body 30 having the thickness d2 of 10 μm to fabricate the package substrate 3, the package substrate 3 can better meet the need for thinning.

Furthermore, when using the thinner core board body 30 with the thickness d2 of 10μm to fabricate the package substrate 3, the total thickness H of the substrate 2a is set to at least 60 μm on both sides of the carrier 9 to avoid problems such as wrinkles or bends of the core board body 30 during the fabrication of the first circuit layer 21 and the first build-up structure 31. Hence, compared to the prior art, the package substrate 3 of the present disclosure can avoid reliability problems such as misalignment or unevenness of the first and second circuit layers 21, 22 and the first and second wiring layers 311, 321.

Also, by using a thermal release film as the support member 8, the core board body 20 can be bonded onto opposite sides of the support member 8 to facilitate mass production.

The present disclosure also provides a package substrate 2, 3, which comprises: a core board body 20, 30, a first circuit layer 21 and a second circuit layer 22.

The core board body 20, 30 has a first side 20a, 30a, a second side 20b, 30b opposing the first side 20a, 30a, and at least one conductive via 200 connecting the first side 20a, 30a and the second side 20b, 30b, wherein the thickness d1, d2 of the core board body 20, 30 is less than or equal to 20 μm.

The first circuit layer 21 is formed on the first side 20a, 30a of the core board body 20, 30 and is electrically connected to the conductive via 200.

The second circuit layer 22 is formed on the second side 20b, 30b of the core board body 20, 30 and is electrically connected to the conductive via 200.

In an embodiment, the package substrate 3 further comprises a first build-up structure 31 disposed on the first side 30a of the core board body 30 and on the first circuit layer 21, wherein the first build-up structure 31 includes at least one first insulating layer 310 formed on the core board body 30 and a first wiring layer 311 formed on the first insulating layer 310 and electrically connected to the first circuit layer 21. For example, the thickness r1 of the first insulating layer 310 is less than or equal to 10 μm.

In an embodiment, the package substrate 3 further comprises a second build-up structure 32 disposed on the second side 30b of the core board body 30 and on the second circuit layer 22, wherein the second build-up structure 32 includes at least one second insulating layer 320 formed on the core board body 30 and a second wiring layer 321 formed on the second insulating layer 320 and electrically connected to the second circuit layer 22. For example, the thickness r2 of the second insulating layer 320 is less than or equal to 10 μm.

In summary, in the package substrate and fabricating method thereof of the present disclosure, the package substrate is made by using a core board body with a thickness thinner than that of a conventional core board body, such that the package substrate can meet the requirement of thinning.

Furthermore, when the core board body with a thin thickness is used to fabricate the package substrate, the total thickness of the substrate on both sides of the carrier is set to be at least 60 μm to avoid the problems such as wrinkles or bends of the core board body during the fabrication of the first circuit layer (and the first build-up structure). Hence, compared to the prior art, the package substrate of the present disclosure is able to avoid problem of reliability such as the misalignment or unevenness of the first and second circuit layers (and the first and second wiring layers).

Also, by using the thermal release film as a support member, a better stress support is provided, so that the core board body can be bonded onto the opposite sides of the support member to facilitate mass production.

In addition, it is possible to fabricate thin core board bodies or thin first and second insulating layers for package substrates without the use of special equipment, thus facilitating the control of production costs.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package substrate, comprising:
a core board body having a first side, a second side opposing the first side, and at least one conductive via connecting the first side and the second side, wherein a thickness of the core board body is less than or equal to 20 micrometers;
a first circuit layer formed on the first side of the core board body and electrically connected to the conductive via; and
a second circuit layer formed on the second side of the core board body and electrically connected to the conductive via.

2. The package substrate of claim 1, further comprising a first build-up structure disposed on the first side of the core board body and on the first circuit layer, wherein the first build-up structure comprises at least one first insulating layer formed on the core board body and a first wiring layer formed on the first insulating layer and electrically connected to the first circuit layer.

3. The package substrate of claim 2, wherein a thickness of the first insulating layer is less than or equal to 10 micrometers.

4. The package substrate of claim 1, further comprising a second build-up structure disposed on the second side of the core board body and on the second circuit layer, wherein the second build-up structure comprises at least one second insulating layer formed on the core board body and a second wiring layer formed on the second insulating layer and electrically connected to the second circuit layer.

5. The package substrate of claim 4, wherein a thickness of the second insulating layer is less than or equal to 10 micrometers.

6. A method of fabricating a package substrate, comprising:
providing a carrier, wherein the carrier comprises a support board body having a metal layer, and a substrate is formed on two opposite sides of the support board body, and a total thickness of the carrier and the substrate is at least 60 micrometers, wherein the substrate has a core board body, the core board body has a first side and a second side opposing the first side, and the core board body is bonded to the metal layer of the carrier via the second side thereof;
forming a first circuit layer on the first side of the core board body, and forming at least one conductive via connecting the first side and the second side to electrically connect the first circuit layer to the conductive via, wherein a thickness of the core board body is less than or equal to 20 micrometers;
removing the carrier;
bonding the first side of the core board body to two opposite sides of a support member, respectively;
forming a second circuit layer on the second side of the core board body to electrically connect the second circuit layer to the conductive via; and
removing the support member.

7. The method of claim 6, further comprising forming a first build-up structure on the first side of the core board body and on the first circuit layer, wherein the first build-up structure comprises at least one first insulating layer formed on the core board body and a first wiring layer formed on the first insulating layer and electrically connected to the first circuit layer.

8. The method of claim 7, wherein a thickness of the first insulating layer is less than or equal to 10 micrometers.

9. The method of claim 6, further comprising forming a second build-up structure on the second side of the core board body and on the second circuit layer, wherein the second build-up structure comprises at least one second insulating layer formed on the core board body and a second wiring layer formed on the second insulating layer and electrically connected to the second circuit layer.

10. The method of claim 9, wherein a thickness of the second insulating layer is less than or equal to 10 micrometers.
